(19) United States
(12) Patent Application Publication
(10) Pub. No.: US 2017/0345665 A1
(43) Pub. Date: Nov. 30, 2017

(54) ATOMIC LAYER ETCHING SYSTEMS AND METHODS

(71) Applicant: Tokyo Electron Limited, Minato-ku (JP)

(72) Inventors: Jacques FAGUET, Austin, TX (US); Trace Hurd, Austin, TX (US); Ian Brown, Portland, OR (US)

(73) Assignee: Tokyo Electron Limited, Minato-ku (JP)

(21) Appl. No.: 15/604,345

(22) Filed: May 24, 2017

Related U.S. Application Data
(60) Provisional application No. 62/341,987, filed on May 26, 2016.

(51) Int. Cl. H01L 21/3065; H01L 21/67

(52) U.S. Cl. CPC H01L 21/3065; H01L 21/67069

(57) ABSTRACT

A processing apparatus includes a processing chamber having a substrate holder; a first gas delivery system configured to deliver a first source gas within the processing chamber; a second gas delivery system configured to deliver a second source gas within the processing chamber; an energy activation system; and processing circuitry. The processing circuitry is configured to control first processing parameters for delivery of the first source gas, control second processing parameters for delivery of the second source gas, control processing chamber parameters and energy activation system parameters to cause a reaction of the first source gas and the second source gas with a surface of one or more parts in the processing chamber to etch an atomic layer from the surface of the one or more parts in absence of a plasma, and control vacuum system parameters for removal of one or more reaction gases from the processing chamber.

### RELATED APPLICATION

This application claims priority to U.S. Provisional Application No. 62/341,987 filed on May 26, 2016, which is incorporated in its entirety by reference herein.

### BACKGROUND

Fabrication of integrated circuits (IC) in the semiconductor industry typically employs a plasma to create and assist the surface chemistry that is necessary to remove material from and deposit material onto a substrate within a plasma processing chamber. In general, a plasma is formed within the plasma reactor under vacuum conditions by heating electrons to energies sufficient to sustain ionizing collisions with a supplied process gas. Moreover, the heated electrons can have energy sufficient to sustain dissociative collisions. Therefore, a specific set of gases under predetermined conditions (e.g., chamber pressure, gas flow rate, etc.) are chosen to produce a population of charged species and/or chemically reactive species suitable to a particular process being performed within the chamber. For example, etching processes remove materials from the substrate and deposition processes add materials to the substrate.

One type of high-precision etching is atomic layer etching (ALE). ALE is typically designed as a self-limiting etch technique to systematically remove thin layers of a material from a substrate. Such etching can be executed by exposing a substrate to a plasma that may be transitioned between an adsorption state and a desorption state. Such thin layers can include monolayers or layers of material having a thickness of an atom or molecule. One object of ALE is to precisely remove an amount of material without damaging underlying layers.

The “background” description provided herein is for the purpose of generally presenting the context of the disclosure. Work of the presently named inventors, to the extent it is described in this background section, as well as aspects of the description which may not otherwise qualify as conventional art at the time of filing, are neither expressly nor impliedly admitted as conventional art against the present disclosure.

### SUMMARY

In one embodiment, a processing apparatus includes a processing chamber having a substrate holder; a first gas delivery system configured to deliver a first source gas within the processing chamber; a second gas delivery system configured to deliver a second source gas within the processing chamber; an energy activation system; and processing circuitry. The processing circuitry is configured to control first processing parameters for delivery of the first source gas, control second processing parameters for delivery of the second source gas, control processing chamber parameters and energy activation system parameters to cause a reaction of the first source gas and the second source gas with a surface of one or more parts in the processing chamber to etch an atomic layer from the surface of the one or more parts in absence of a plasma, and control vacuum system parameters for removal of one or more reaction gases from the processing chamber.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a block diagram illustrating a first exemplary ALE system according to one embodiment;

FIG. 2 illustrates an exemplary thermal ALE process in which the first source gas (first reactant) and the second source gas (second reactant) are alternately pulsed according to one embodiment;

FIG. 3 illustrates an exemplary thermal ALE process in which a steady supply of a first reactant is input while a second reactant is pulsed according to one embodiment;

FIG. 4A illustrates a chemical reaction that occurs when a first reactant of Al(acac)₃ contacts an Al₂O₃ film followed by a second reactant of HF according to one embodiment;

FIG. 4B illustrates a chemical reaction that occurs when a first reactant of AlF₃ contacts an Al₂O₃ film followed by a second reactant of Al(acac)₃ according to one embodiment;

FIG. 5A is a graph illustrating mass changes during exposure of the first source gas and the second source gas during AlF₃ atomic layer deposition according to one embodiment;

FIG. 5B is a graph illustrating the growth rate as a function of temperature according to one embodiment;

FIG. 5C is a graph illustrating the mass loss during exposure of the first source gas and the second source gas for three cycles of Al₂O₃ ALE according to one embodiment;

FIG. 6 is a block diagram illustrating a second exemplary ALE system according to one embodiment;

FIG. 7 is a graph illustrating photon enhanced ALE according to one embodiment;

FIG. 8A is a graph illustrating an exemplary thermal ALE process in which the first source gas (first reactant) and the second source gas (second reactant) are alternately pulsed with a single light pulse according to one embodiment;

FIG. 8B illustrates the fluorination process according to one embodiment;

FIG. 8C illustrates the chemical interaction of the photon enhanced ALE process according to one embodiment;

FIG. 9A is a graph illustrating an exemplary thermal ALE process in which the first source gas (first reactant) and the second source gas (second reactant) are alternately pulsed with two light pulses according to one embodiment;

FIG. 9B illustrates the fluorination process according to one embodiment;

FIG. 10 is a block diagram illustrating a third exemplary ALE system according to one embodiment;

FIG. 11 is a block diagram illustrating a multiple processing chamber according to one embodiment;

FIG. 12 illustrates circuitry components separate from the ALE system according to one embodiment;

FIG. 13 is a block diagram of an exemplary computing device according to one embodiment;

FIG. 14 is a flowchart for an exemplary method of etching a surface of a part according to one embodiment; and

FIG. 15 is a flowchart for an alternative method of etching a surface of a part according to one embodiment.

### DETAILED DESCRIPTION

The following descriptions are meant to further clarify the present disclosure by giving specific examples and embodiments of the disclosure. These embodiments are meant to be illustrative, rather than exhaustive. The full scope of the disclosure is not limited to any particular embodiment disclosed in the specification, but rather is defined by the claims.

In the interest of clarity, not all of the features of the implementations described herein are shown and described in detail. It will be appreciated that in the development of any such actual implementation, numerous implementation-specific decisions will be made in order to achieve the developer's specific goals, such as compliance with application- and business-related constraints, and that these specific goals will vary from one implementation to another and from one developer to another.

As noted in the Background above, ALE can provide a high-precision technique for removing thin layers of material. Such techniques can be particularly useful when fabricating gates for transistors. However, the present inventors recognized that there are still challenges for successful implementation of ALE. For example, plasma processing is conventionally used for ALE, and plasma products can damage underlying layers. In addition, throughput is slow since each substrate needs to be individually etched in a conventional ALE plasma-processing system.

Techniques disclosed herein include systems configured to enable thermal atomic layer etching, that is, thin or monolayer etching without using a plasma. Systems herein are configured to thermally etch metal-containing layers without damaging underlying layers. Other embodiments can be used for thermally etching non metal-containing layers, such as silicon-containing and germanium-containing materials. Thermal etching herein can target a particular material for uniform layer removal, such that layers of a given material are equally removed from horizontal surfaces as well as vertical surfaces. Techniques herein can be used for thermally etching gate stacks, fins, nanowires, and contact arrays, for example.

The order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Techniques herein include systems configured to enable thermal ALE, that is, thin or monolayer etching without using a plasma. Systems herein are configured to thermally etch films without damaging underlying layers. Systems and associated circuitry herein control delivery of a first source gas and delivery of a second source gas, as well as control the temperature of a part, substrate, or wafer being processed and control the chamber pressure to remove monolayers of a given material from the part, substrate, or wafer. Other parameters, such as the pressure and flow rate of the first and/or second source gas, the simultaneous or pulsed input of the first or second source gas, and enhanced adsorption of a byproduct of the thermal ALE also determine and control a thermally ALE part, substrate, or water.

Thermal ALE can be executed by fluorination of an exposed surface of a part, substrate, or wafer. For example, an upper surface (uncovered or exposed surface) of a part, substrate, or wafer may have a layer of aluminum oxide (Al₂O₃). Hydrogen fluoride is delivered to the Al₂O₃ surface. The Al₂O₃ surface is sufficiently heated to cause fluorination of the aluminum oxide, resulting in aluminum fluoride (AlF₃), with water vapor being released. A metal organic source gas is delivered to the part, substrate, or wafer, such as tin acetylacetonate (Sn(acac)₂), which results in a ligand exchange. The aluminum fluoride layer reacts with the metal organic source gas to form two volatile compounds, such as SnF(acac) and Al(acac)₃, which can be vented out of the processing chamber. This technique can remove a layer of aluminum oxide. The amount of material removed is dependent on an amount of fluorination. This reaction can be self-limiting to remove approximately a monolayer of material, that is, a thickness of a given molecule is removed.

Embodiments described herein include an ALE system having an energy activation system for processing one or more parts, substrates, or wafers. In a first embodiment, the energy activation system is a heating system. In a second embodiment, the energy activation system is a light and/or electromagnetic radiation system.

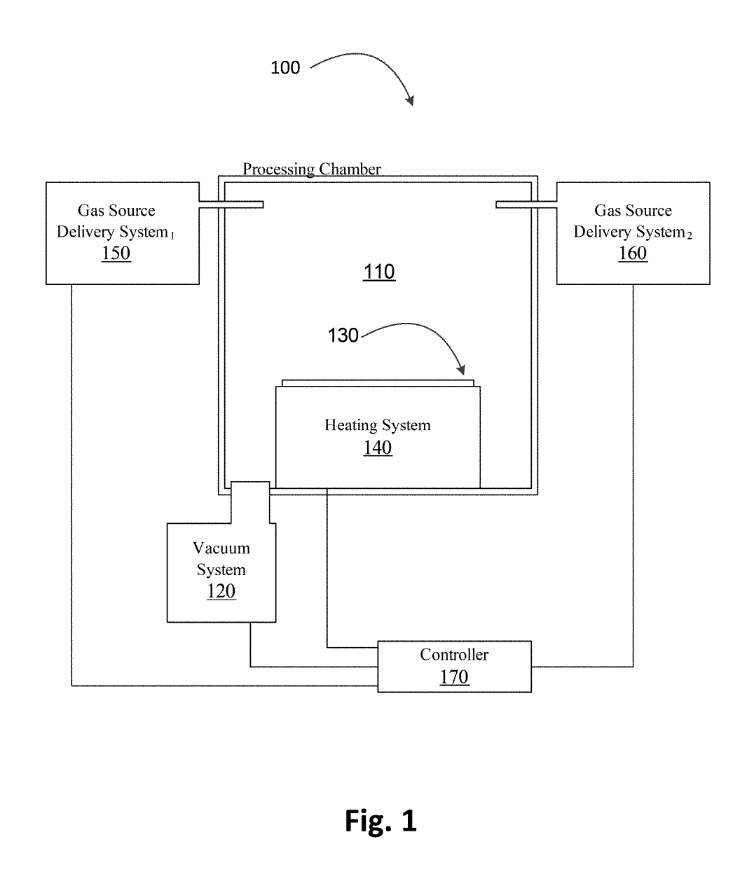

FIG. 1 is a block diagram of a first exemplary ALE system 100. ALE system 100 has a processing chamber 110. A vacuum system 120 controls the environment within the processing chamber 110, such as a pressurized environment. The processing chamber 110 includes a holding mechanism 130 for holding a part to be processed, such as one or more parts, substrates, or wafers. The holding mechanism 130 can be a chuck, boat, etc. The part, substrate, or wafer can have various films to be removed, including a metal-containing film on a working surface of the part, substrate, or wafer.

A heating system 140 is configured to heat the part, substrate, or wafer positioned within the processing chamber 110 to enable ALE without plasma. For example, the substrate can be heated to at least 100 degrees Celsius or to at least 150 degrees Celsius. The heating system may heat the part, substrate, or wafer up to 300 degrees Celsius or up to 400 degrees Celsius. The one or more parts, substrates, or wafers can be heated to between 100 degrees Celsius and 400 degrees Celsius, or more than 400 degrees Celsius. As a result, one or more parts, substrates, or wafers can be heated to enable the thermally reactive etching process. A temperature to which a part, substrate, or wafer is heated is dependent on a type of material on the part, substrate, or wafer to be etched, and the type of reactants used for thermal etching. The heating system 140 can be configured to directly heat the part, substrate, or wafer positioned within the processing chamber 110 or to heat the processing chamber 110 in general.

A transition temperature is the temperature between a lower deposition temperature of the material being deposited and a higher etching temperature of the layer being etched from the part, substrate, or wafer. The specific transition temperature is determined by certain given parameters, such as the deposition material and the etched layer material. The specific transition temperature can also be controlled by many parameters, such as the pressure of the first and/or second source gas, the chamber pressure, and certain purging parameters. The purging parameters include, but are not limited to the type of purging gas, the purging gas pressure, and the efficiency by which the purging gas is cleared or cleaned from the surface of the etched part, substrate, or wafer.

ALE system 100 includes a first process gas delivery system 150 configured to deliver a first source gas to the processing chamber 110, such as a fluorine source gas. Examples of such fluorine source gas include hydrogen fluoride (HF), difluoride (F₂), xenon difluoride (XeF₂), xenon tetrafluoride (XeF₄), xenon hexafluoride (XeF₆), nitrogen trifluoride (NF₃), and/or other gaseous HF or fluorine forms. The first process gas delivery system 150 can be configured to deliver the fluorine source gas as a dry gas, with a carrier gas, or with a fluorine adsorption enhancing agent such as water vapor, ammonia, methanol, ethanol, etc. Other source gases used with the first process gas delivery system 150 are contemplated by embodiments described herein.

ALE system 100 includes a second process gas delivery system 160 configured to deliver a second source gas to the processing chamber 110, such as a metal organic source gas. Examples of such metal organic source gases include trimethyl aluminum (TMA), metal acetylacetonates such as tin acetylacetonate (Sn(acac)₂) and aluminum acetylacetonate Al(acac)₃), or other metals plus chelators of the beta diketone class of compounds, including pentane-2 and 4-dione variants. The second process gas delivery system 160 can use a carrier gas (such as N₂, Ar, He, or another inert gas) with the metal organic source gas.

The vacuum system 120 is configured to remove gases from the processing chamber and maintain a predetermined pressure within the processing chamber 110. The predetermined pressure can range from anywhere from 0.1 Torr to atmospheric pressure. In one embodiment, the predetermined pressure ranges from 1 Torr to 10 Torr.

A controller 170 is configured with processing circuitry to selectively control heating within the processing chamber 110, the pressure of the processing chamber 110, the first process gas delivery system 150, and the second process gas delivery system 160 such that, when processing the part, substrate, or wafer, monolayers of material are sequentially removed by ALE. In one example, a fluorine source is provided to the processing chamber 110, followed by a chamber purge. A metal organic is then provided, followed by another chamber purge. This cycle can be repeated until the desired etch depth is achieved.

Table 1 illustrates exemplary transition temperatures for a particular part, substrate, or water, when processed with a first source gas and two different second source gases. Each illustrated example had a chamber pressure of 1.5 Torr and a nitrogen purge gas at 1 Torr.

TABLE 1
Transition Temperatures of Thermal ALE

| | | 2^{nd} | Transition | Chamber | |
|---|---|---|---|---|---|
| Material | 1^{st} Reactant | Reactant | T | P | Purge Gas |
| Al₂O₃ | HF | Sn(acac)₃ | 150 C. | 1.5 Torr | N₂ at 1 Torr |
| Al₂O₃ | HF | TMA | 230 C. | 1.5 Torr | N₂ at 1 Torr |

In other embodiments, the controller 170 can cause the first and second process gases to be present in the processing chamber at the same time to continuously flow a first source gas while also pulsing a second source gas. Pulse timing, gas flow rates, and/or gas ratios of the first and second process gases may be controlled to achieve desired process results. For example, a continuous flow of fluorine-based source gas can be introduced first. A second metal organic source gas can be pulsed to overcome the partial pressure of the first source gas and displace it from the surface of the part, substrate, or wafer to complete ligand exchange. The second metal organic source gas can subsequently stop flowing to allow the first source gas to saturate the etched surface of the part, substrate, or wafer for additional fluorination.

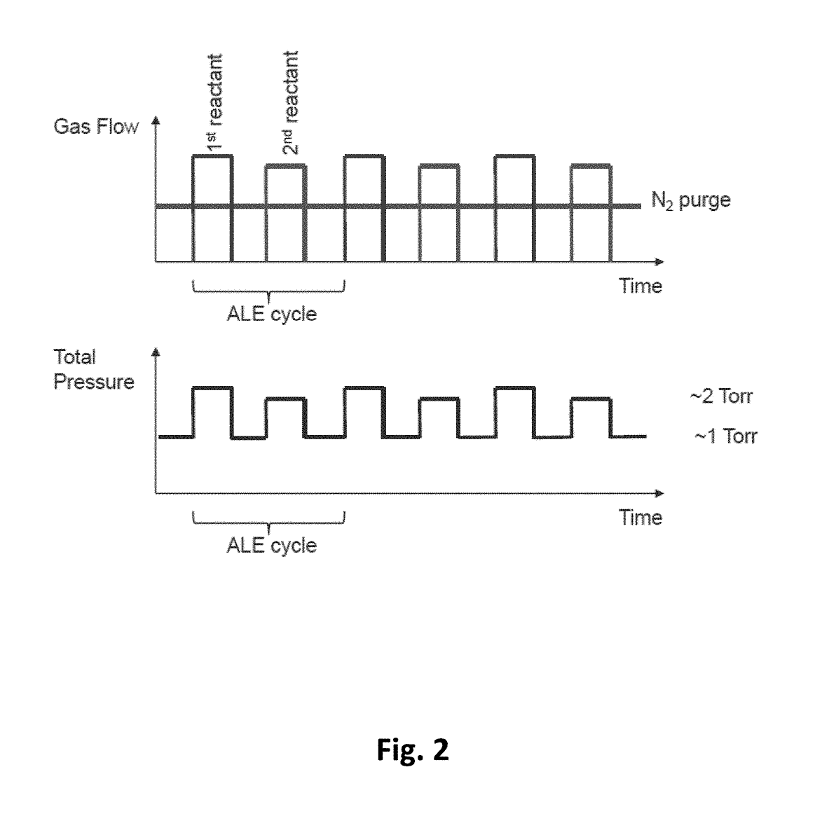

FIG. 2 illustrates an exemplary thermal ALE process in which the first source gas (first reactant) and the second source gas (second reactant) are alternately pulsed. In the upper graph, one ALE cycle includes a pulsed input of the first reactant followed by a pulsed input of the second reactant. A nitrogen (N₂) purge is implemented throughout the ALE cycling. In the lower graph, the chamber pressure is illustrated. In between the pulsed reactants, a chamber pressure of approximately 1 Torr exists. The chamber pressure reaches approximately 2 Torr during pulsing of either reactant, wherein the chamber pressure is slightly higher during pulsing of the first reactant compared to pulsing of the second reactant.

FIG. 2 is given for exemplary purposes to illustrate sequential introduction of two reactant gases. Other pressures, times, reactant gases, and conditions are contemplated by embodiments described herein.

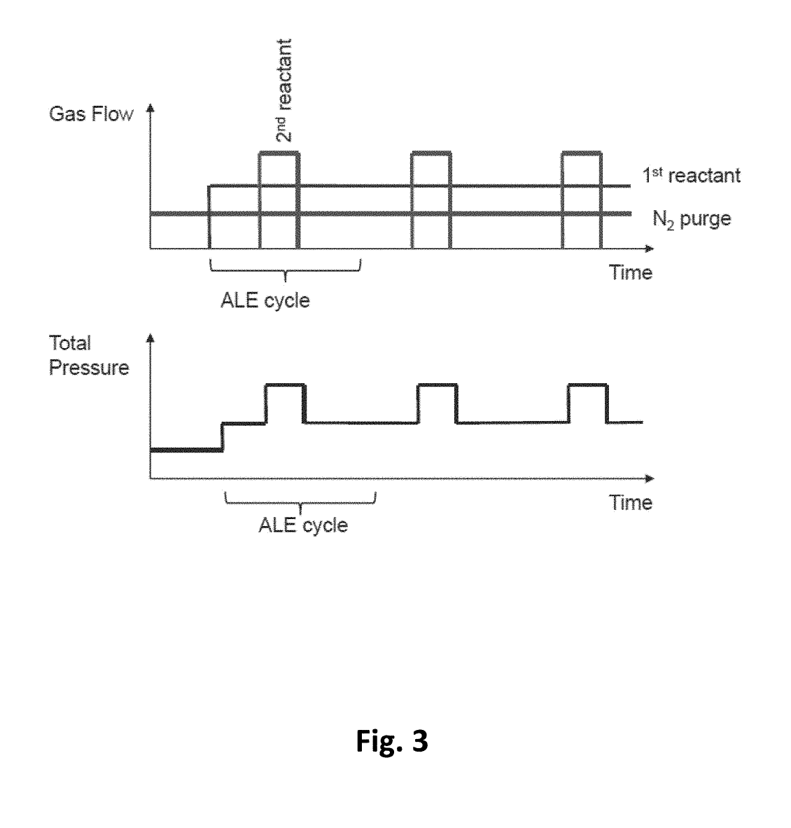

FIG. 3 illustrates an exemplary thermal ALE process in which a steady supply of a first reactant is input, while a second reactant is pulsed. In the upper graph, the first reactant is supplied at a lower gas flow rate than the pulsed second reactant, while a continuous nitrogen purge is implemented. The lower graph of FIG. 3 illustrates a chamber pressure, which illustrates a stepped function between the pulsed second reactant introductions into the chamber.

FIG. 3 is given for exemplary purposes to illustrate continuous introduction of a first reactant gas and a pulsed introduction of a second reactant gas. Other pressures, times, reactant gases, and conditions are contemplated by embodiments described herein.

A temperature of the part, substrate, or wafer drives a competition between the deposition and etching processes. The second source gas (such as AlF₃) of the atomic layer deposition (ALD) is at a temperature lower than the transition temperature, while the ALE of Al₂O₃ is at a higher temperature than the transition temperature. The transition temperature depends on the purge gas type and the purge gas pressure. The amount of material removed at each ALE cycle is controlled by the adsorbed HF amount for this particular example.

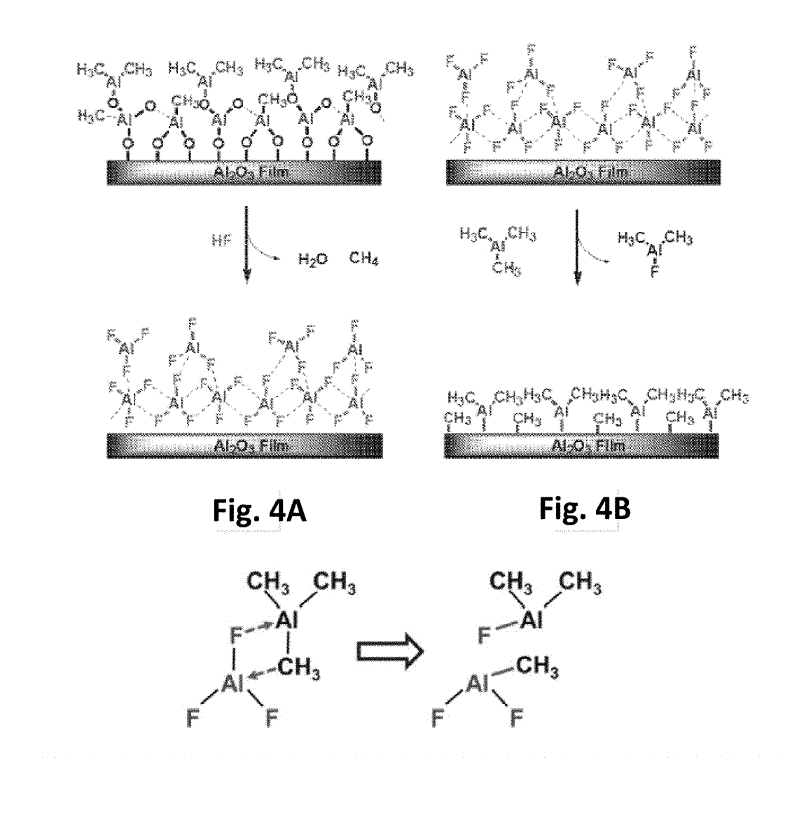

FIG. 4A illustrates a chemical reaction that occurs when a first reactant of Al(acac)₃ contacts an Al₂O₃ film, followed by a second reactant of HF. FIG. 4B illustrates a chemical reaction that occurs when a first reactant of AlF₃ contacts an Al₂O₃ film, followed by a second reactant of Al(acac)₃. The combined reaction results in two volatile compounds, AlF(acac) and Al(acac)₂.

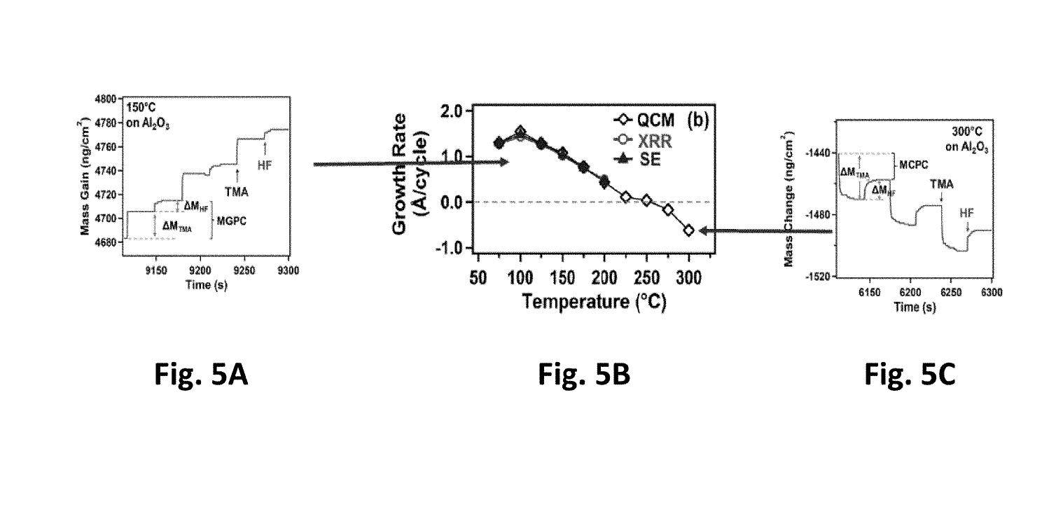

FIG. 5A is a graph illustrating mass gain per cycle (MGPC) during exposure of the first source gas and the second source gas during AlF₃ atomic layer deposition. FIG. 5B is a graph illustrating the growth rate as a function of temperature according to quartz crystal monitor (QCM), X-ray reflectometry (XRR), and spectroscopic ellipsometry (SE). FIG. 5C is a graph illustrating the mass change per cycle (MCPC) during exposure of the first source gas and the second source gas for three cycles of Al₂O₃ ALE.

When the substrate temperature is less than the transition temperature, the residence time of HF reactant gas, as well as intermediate products of the fluorination process is long enough to allow for the AlF₃ film to grow when it is exposed to the next organo-metallic reactant. When the substrate temperature is approximately equal to the transition temperature, both AlF₃ deposition and Al₂O₃ etching occur simultaneously.

Heating within the processing chamber 110 can include processing circuitry to control a platform heater, chamber wall heaters, and radiant heating (such as infrared). Some embodiments include separate controls for different types of heaters (for example, conductive platform heater versus radiant chamber heater). The processing circuitry of the controller 170 can be configured to simultaneously deliver the first source gas and the second source gas or sequentially deliver the first source gas and the second source gas, such as by cycle sequential delivery of the first source gas and the second source gas.

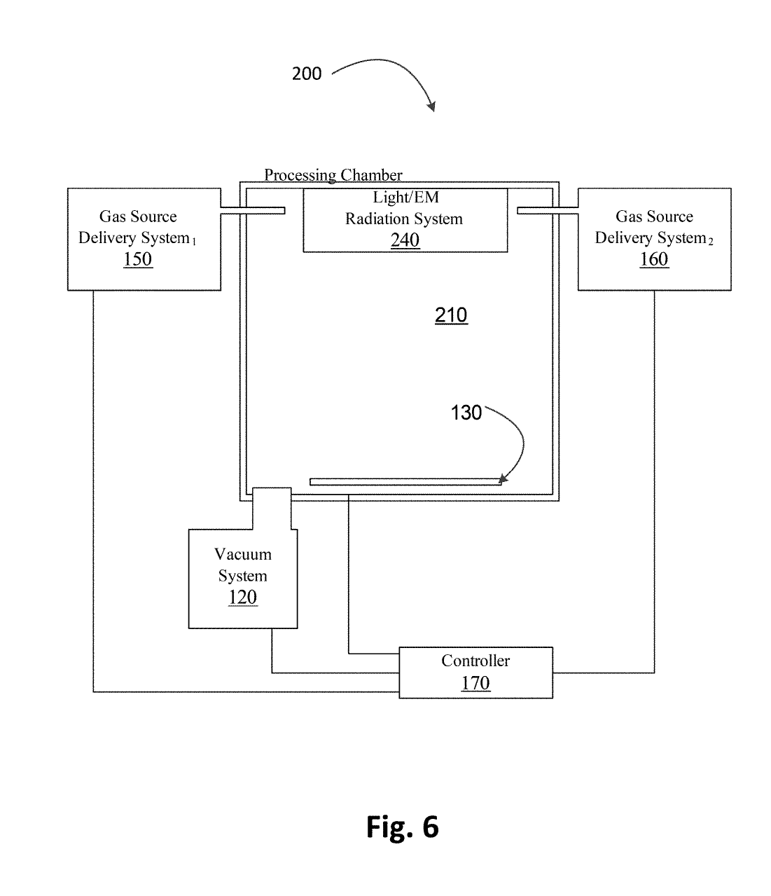

FIG. 6 is a block diagram of a second exemplary ALE system 200 having a processing chamber 210 in which the activating energy is a light/electromagnetic radiation system 240. Light/electromagnetic radiation system 240 is shown in FIG. 6 as a single block on the ceiling of the processing chamber 210. However, the actual location and layout of the one or more components of light/electromagnetic radiation system 240 may vary. For example, multiple light sources may be located on one or more walls or on the ceiling of the processing chamber 210. Other features illustrated in FIG. 6 are the features illustrated in FIG. 1 with like numbers.

The light/electromagnetic radiation system 240 can be used in place of, or in addition to, heat as a mechanism to drive or enhance gas phase and/or surface reactions, such as adsorption and/or desorption of materials on a part, substrate, or wafer. In one embodiment, light/electromagnetic radiation system 240 includes a light exposure system configured to expose the part, substrate, or wafer to radiation and/or expose process gases to radiation, such as a lateral light projection.

The radiation can include any light wavelength, such as ultraviolet (UV), visible, infrared (IR), etc. In some systems, two or more light wavelengths can be used. The exposure can be simultaneous or sequential exposure. The selected wavelength(s) can be based on a particular material being treated to optimize adsorption and desorption. Two or more light sources can also be used. For example, two lamps configured for flash and flood exposure can be used.

Controller 170 is configured with processing circuitry to selectively control heating within the processing chamber 210, the pressure of the processing chamber 210, the first process gas delivery system 150, and the second process gas delivery system 160 such that, when processing the part, substrate, or wafer, monolayers of material are sequentially removed by ALE. In one example, a fluorine source is provided to the processing chamber 210, followed by a chamber purge. A metal organic is then provided, followed by another chamber purge. This cycle can be repeated until the desired etch depth is achieved.

In other embodiments, the controller 170 can cause the first and second process gases to be introduced into the processing chamber 210 at the same time. For example, the fluorine source and metal organic can be introduced at the same time, or fluorine and beta diketone compounds can be introduced at the same time. Further, the ALE process may change between a sequential pulsed process and a simultaneous flow process to achieve desired results. Pulse timing, gas flow rates, and/or gas ratios of the first and second process gases may be controlled to achieve desired process results.

The light source can be used to enhance the etching process. In one embodiment, the light source can directly impact the reactivity of spaces that are being adsorbed within the surface of the part, substrate, or wafer. In a second embodiment, the adsorption of the byproduct is enhanced by a flash of ultraviolet or physical light to prevent the etching from continuing. Light of the same wavelength or different wavelengths can be used.

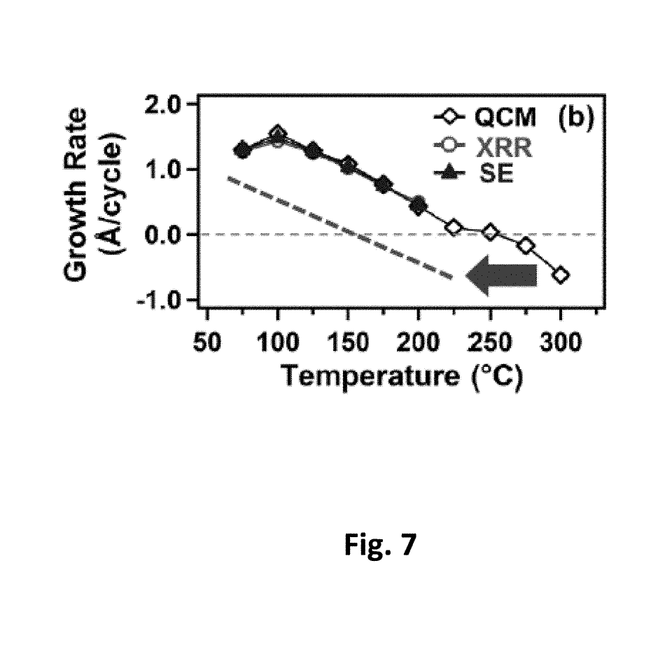

FIG. 7 is a graph illustrating photon enhanced ALE. FIG. 7 is the graph illustrated in FIG. 5B. In addition, a dashed line with a solid arrow next to it in FIG. 7 indicates the lower temperatures at which the process can be implemented by using electromagnetic radiation with the ALE process. Since thermal ALE is desorption limited, the process allows a lower substrate temperature to be used by delivering pulses of radiation/light energy for ultra-fast desorption of the adsorbed reactants and by-products of reaction. This occurs prior to subsequent reactant exposure.

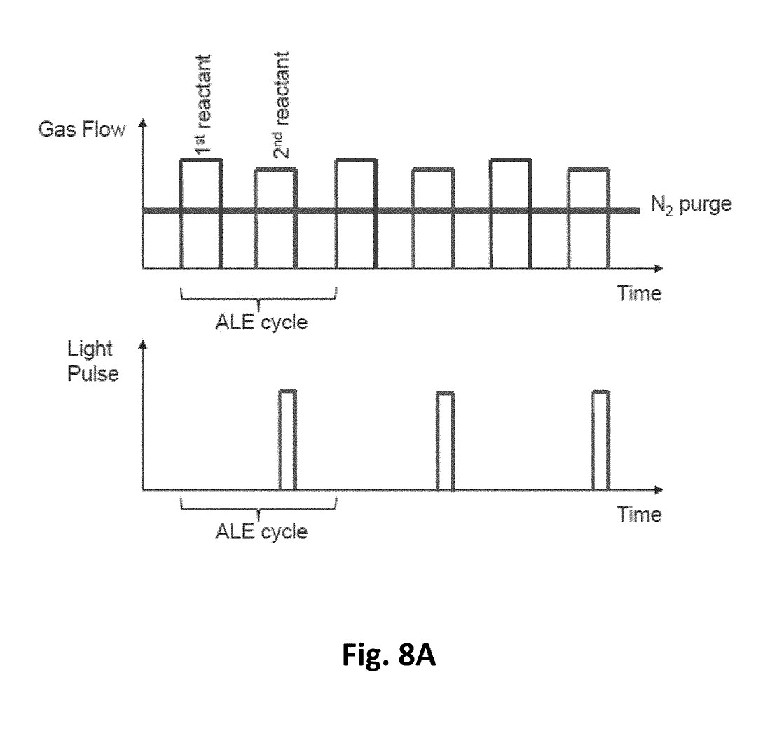

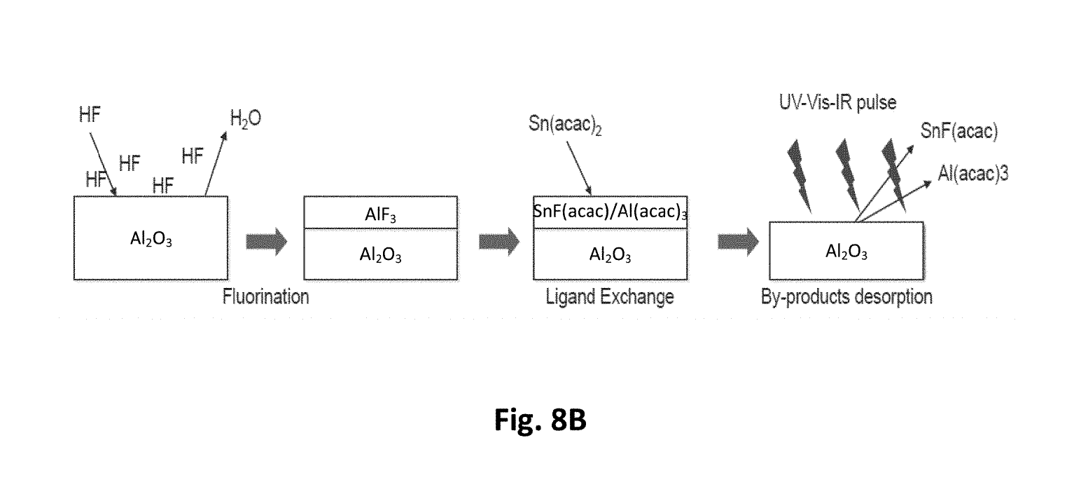

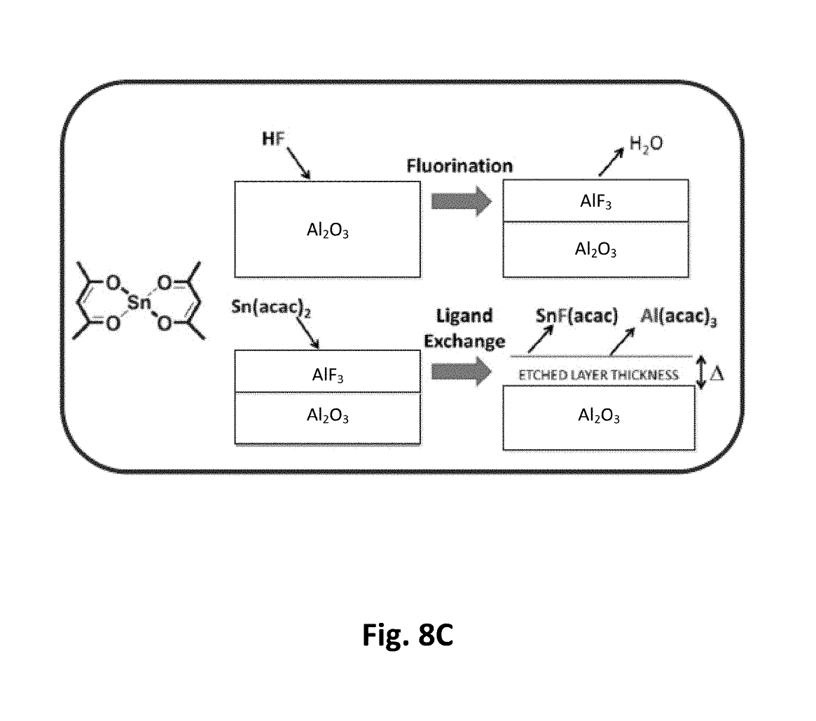

FIG. 8A includes an upper graph illustrating the exemplary thermal ALE process of FIG. 2 in which the first source gas (first reactant) and the second source gas (second reactant) are alternately pulsed. The lower graph in FIG. 8A illustrates the point at which a light pulse is introduced into each ALE cycle. In the example of FIG. 8A, the pulse is introduced at the end of the second reactant introduction.

FIG. 8B illustrates the fluorination process, followed by the ligand exchange process of ALE. After the ligand exchange process, a light pulse, such as an ultraviolet (UV), visual, or infrared (IR) pulse is directed towards the part, substrate, or wafer to enhance by-product desorption.

FIG. 8C illustrates the chemical interaction of the photon enhanced ALE process. When HF source gas interacts with the Al₂O₃ surface, fluorination of the part, substrate, or wafer surface occurs to form AlF₃. When the surface is subsequently exposed to Sn(acac)₂, ligand exchange occurs to form SnF(acac) and Al(acac)₃ volatile compounds.

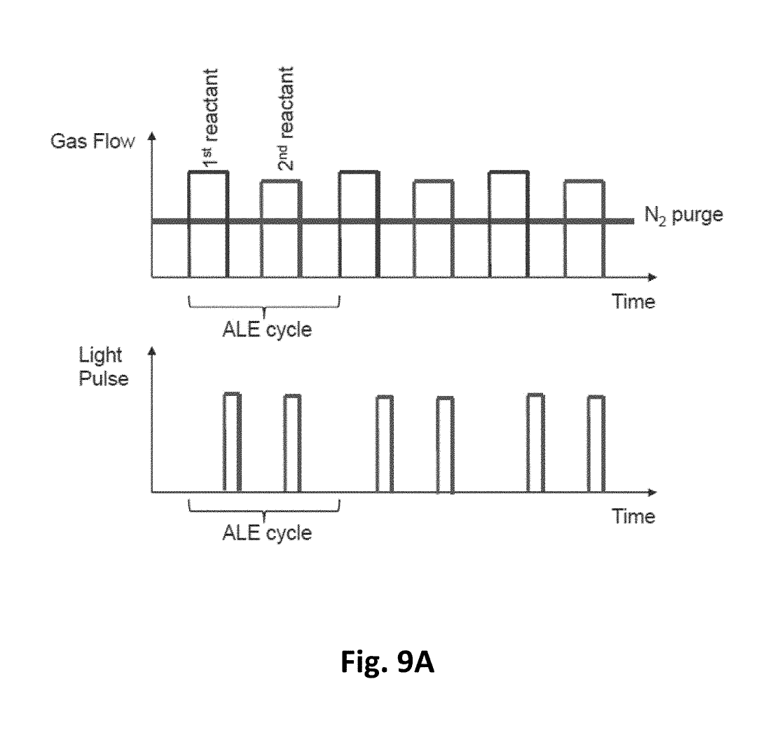

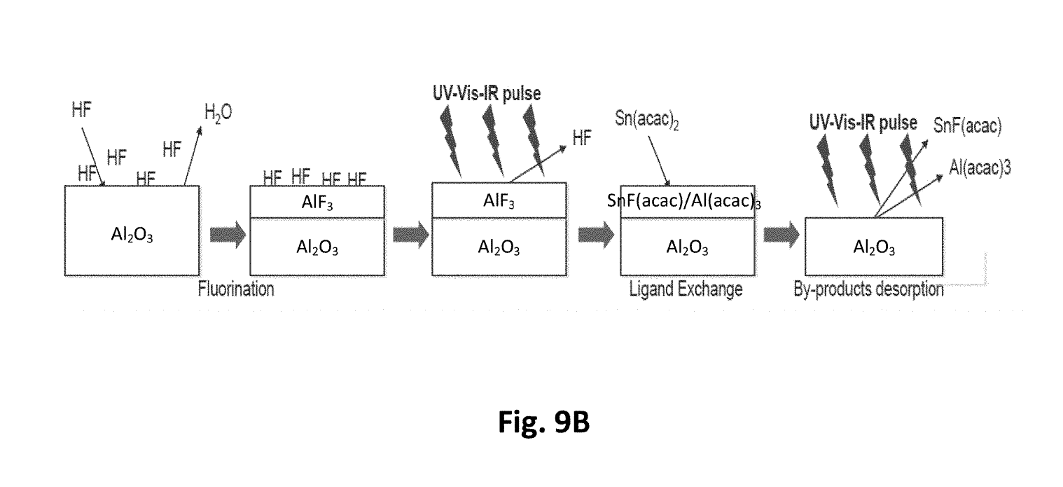

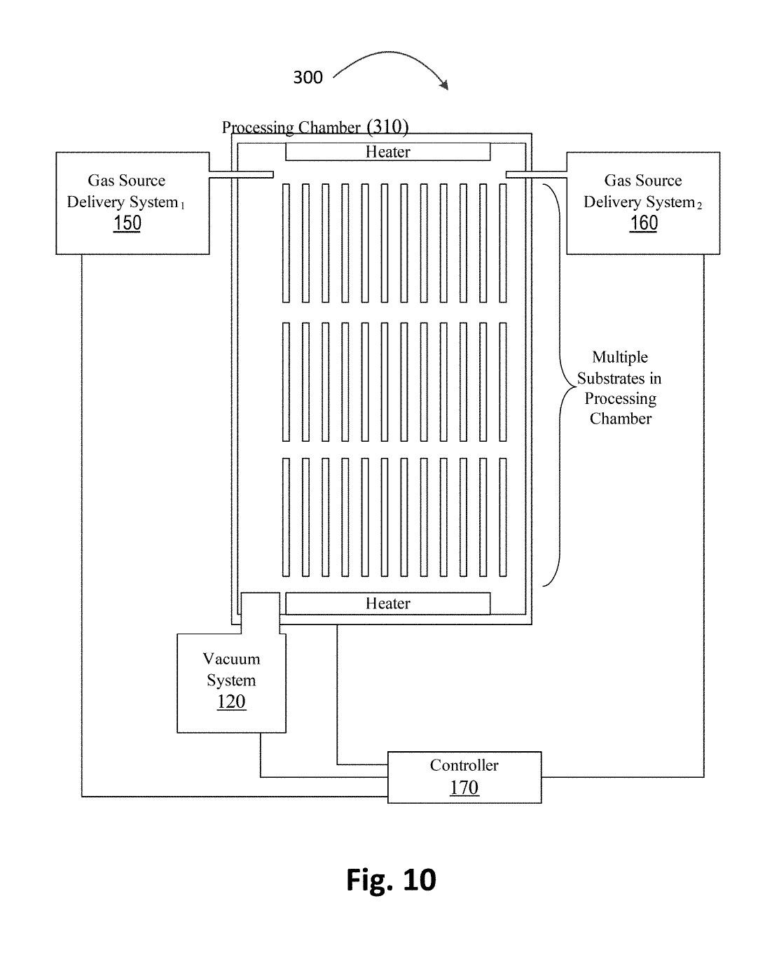

FIG. 9A includes an upper graph illustrating the exemplary thermal ALE process of FIG. 2 in which the first source gas (first reactant) and the second source gas (second reactant) are alternately pulsed. The lower graph in FIG. 9A illustrates exposure to two photon pulses for each ALE cycle. In the graph illustrated, a first pulse occurs at the end of the first reactant introduction and a second pulse occurs at the end of the second reactant introduction.

FIG. 9B illustrates the fluorination process, followed by a first pulse of light, such as an UV, visual, or IR pulse directed towards the part, substrate, or wafer. The first light pulse is followed by ligand exchange on the surface of the part, substrate, or wafer. A second light pulse is subsequently directed towards the substrate to obtain by-product desorption.

Photon-enhanced desorption enables lower substrate temperatures to be used. The substrate temperature is lowered before organo-metallic reactant exposure by vaporizing the adsorbed HF layer, which prevents a competing AlF₃ deposition. The substrate temperature is also lowered after organo-metallic ligand exchange by vaporizing reaction by-products, which exposes the unetched Al₂O₃ surface to subsequent fluorination by HF exposure.

In some embodiments, the processing chamber can be configured as a furnace tool. FIG. 10 is a block diagram illustrating a third exemplary ALE system 300 in which a processing chamber 310 is configured to heat treat multiple parts, substrates, or wafers simultaneously and to perform thermal ALE on the multiple parts, substrates, or wafers at the same time. ALE system 300 improves throughput, compared to plasma-based ALE which can only process one part, substrate, or wafer at a time. In one embodiment, ALE system 300 is configured to execute thermal-based ALE and to execute a chemical oxide removal process by having a fluorine-based gas delivery system and a nitrogen-based gas delivery system.

Techniques herein can process multiple parts, substrates, or wafers at one time. This can be advantageous because an ALE removal process is relatively slow compared to other semiconductor fabrication techniques. FIG. 10 illustrates multiple parts, substrates, or wafers within a single processing chamber 310. Although thermal ALE techniques can be comparatively slow, embodiments described herein enable multiple parts, substrates, or wafers to be simultaneously processed in close proximity to each other. In contrast, plasma-based ALE typically processes a single part, substrate, or wafer at one time.

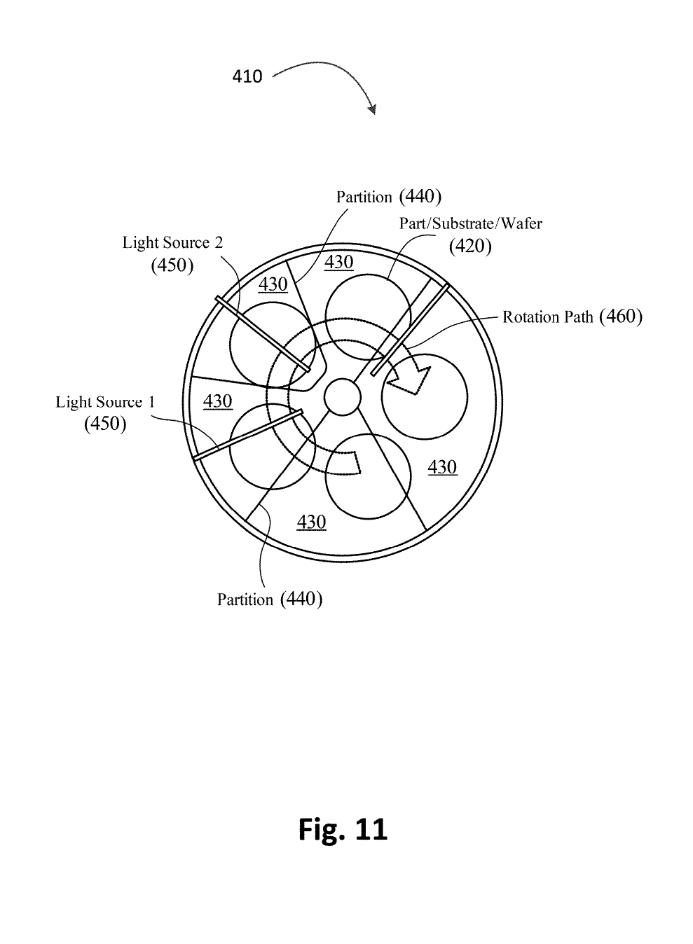

FIG. 11 is a block diagram illustrating a multiple processing chamber 410 configured to move each part, substrate, or wafer 420 among multiple deposition and removal stations. Processing chamber 410 has multiple stages of multiple treatment zones or sub-chambers 430 through which several parts, substrates, or wafers 420 are moved. The sub-chambers 430 are delineated by partitions 440, such as a physical wall or an air knife. For example, a substrate holder can be configured to rotate about a center point, thereby moving given parts, substrates, or wafers 420 from one treatment zone of a first sub-chamber 430 to another treatment zone of a second sub-chamber 430. Some sub-chambers 430 include one or more light sources 450, which can have different wavelengths to flood and/or flash expose the parts, substrates, or wafers 420 to assist with adsorption and desorption.

In an exemplary process, the part, substrate, or wafer 420 can be rotated along a rotation path 460 to a first sub-chamber 430 for fluorination, then rotated or moved to an adjacent sub-chamber 430 for ligand exchange (for metal-containing layers) or other volatilization of a given modified layer to be removed. The part, substrate, or wafer 420 can then be rotated to an air purge sub-chamber 430 or to another fluorination sub-chamber 430.

Other ALE processes using processing chamber 410 are contemplated by embodiments described herein for thermally etching monolayers of material from a given part, substrate, or wafer to be processed. For example, one or more parts, substrates, or wafers are positioned in a processing chamber that includes a platform or holding mechanism. The one or more parts, substrates, or wafers are heated above 100 degrees Celsius. A first process gas is delivered to the processing chamber. The first process gas includes a fluorine source gas. Chamber heating and chamber pressure are controlled such that the fluorine source gas reacts with an uncovered layer on the part, substrate, or wafer to form a fluorinated layer.

A second process gas is delivered to the processing chamber. The second process gas includes a metal organic source gas. Chamber heating and chamber pressure are controlled such that the metal organic source gas reacts with the fluorinated layer causing the fluorinated layer to become volatile. Gases are removed from the processing chamber including volatile products from the fluorinated layer. Forming the fluorinated layer and removing the fluorinated layer can be repeated until reaching a predetermined amount of material removal.

A controller is configured with processing circuitry to selectively control heating within the processing chamber 410, the pressure of the processing chamber 410, the first process gas delivery system 150, and the second process gas delivery system 160 such that, when processing the part, substrate, or wafer, monolayers of material are sequentially removed by ALE. In one example, a fluorine source is provided to the processing chamber 410, followed by a chamber purge. A metal organic is then provided, followed by another chamber purge. This cycle can be repeated until the desired etch depth is achieved. As illustrated in FIG. 11, each process can be executed in a separate sub-chamber 430.

In other embodiments, the controller can cause the first and second process gases to be introduced into the processing chamber 410 at the same time. For example, the fluorine source and metal organic can be introduced at the same time, or fluorine and beta diketone compounds can be introduced at the same time. Further, the ALE process may change between a sequential pulsed process and a simultaneous flow process to achieve desired results. Pulse timing, gas flow rates, and/or gas ratios of the first and second process gases may be controlled to achieve desired process results.

Accordingly, a precisely-defined amount of material can be removed, which can be beneficial when fabricating gate electrodes and other structures. In other embodiments, the first process gas and the second process gas can be simultaneously delivered to the processing chamber, or they can be sequentially delivered to the processing chamber, such as by pulsing or cycling between the first process gas and the second process gas.

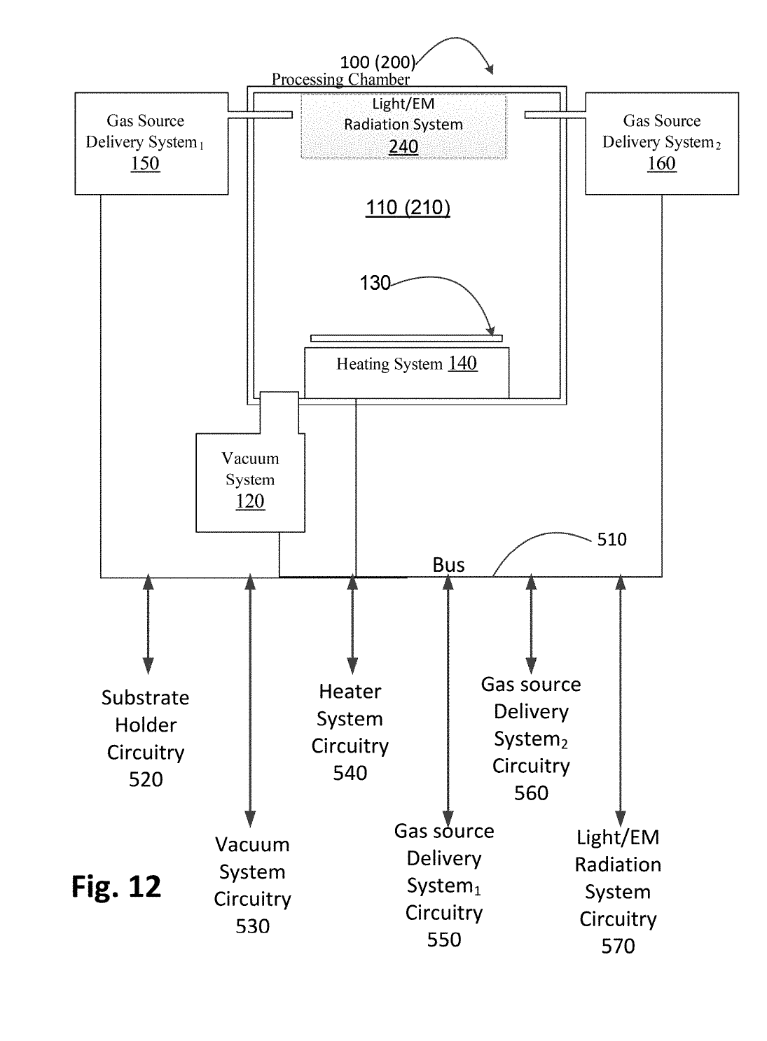

FIG. 1 illustrates controller 170 as an integral part of ALE system 100. Likewise, FIG. 6 illustrates controller 170 as an integral part of ALE system 200. FIG. 12 illustrates an alternative embodiment in which circuitry components are separate from ALE system 100 or ALE system 200. Circuitry components are connected to the ALE system 100 or 200, via a bus 510.

Substrate holder circuitry 520 has processing circuitry configured to monitor the holding mechanism 130 in which one or more parts, substrates, or wafers are mounted thereon for processing. The substrate holder circuitry 520 is configured to monitor a single part, substrate, or wafer such as illustrated in FIG. 1 or FIG. 6. The substrate holder circuitry 520 is also configured to monitor multiple parts, substrates, or wafers such as illustrated in FIG. 10. The substrate holder circuitry 520 is also configured to monitor multiple parts, substrates, or wafers as they are rotated through multiple sub-chambers of a processing chamber as illustrated in FIG. 11.

Vacuum system circuitry 530 has processing circuitry configured to regulate the vacuum environment within the processing chambers 110, 210, and 310. In FIG. 11, the vacuum system circuitry 530 has processing circuitry configured to regulate the vacuum environment within each of the sub-chambers 430 of the processing chamber 410.

Heater system circuitry 540 has processing circuitry configured to regulate the heating energy activation system 140 within the processing chamber 110 of FIG. 1. The processing circuitry of heater system circuitry 540 controls each of the heaters present, such as the platform heater and one or more wall or chamber heaters present within the processing chamber 110.

Gas source delivery system₁ circuitry 550 has processing circuitry configured to regulate the first source gas within processing chamber 110, 210, 310, or 410. Gas source delivery system₂ circuitry 560 has processing circuitry configured to regulate the second source gas within processing chamber 110, 210, 310, or 410.

Light and electromagnetic radiation system circuitry 570 has processing circuitry configured to regulate the light and electromagnetic radiation energy activation system 240 within the vacuum chamber 210 of FIG. 6. The light and electromagnetic radiation system circuitry 570 controls processes, such as one or more light sources, the wavelength(s) used, and the exposure parameters. Light/electromagnetic radiation system 240 can be used in lieu of or in addition to heating system 140.

The processing circuitry illustrated in FIG. 12 selectively controls heating within the processing chamber 110 or 210, the pressure of the processing chamber 110 or 210, the first process gas delivery system 150, and the second process gas delivery system 160 such that, when processing the part, substrate, or wafer, monolayers of material are sequentially removed by ALE. In one example, a fluorine source is provided to the processing chamber 110 or 210, followed by a chamber purge. A metal organic is then provided, followed by another chamber purge. This cycle can be repeated until the desired etch depth is achieved.

In other embodiments, the processing circuitry can cause the first and second process gases to be introduced into the processing chamber 110 or 210 at the same time. For example, the fluorine source and metal organic can be introduced at the same time, or fluorine and beta diketone compounds can be introduced at the same time. Further, the ALE process may change between a sequential pulsed process and a simultaneous flow process to achieve desired results. Pulse timing, gas flow rates, and/or gas ratios of the first and second process gases may be controlled to achieve desired process results.

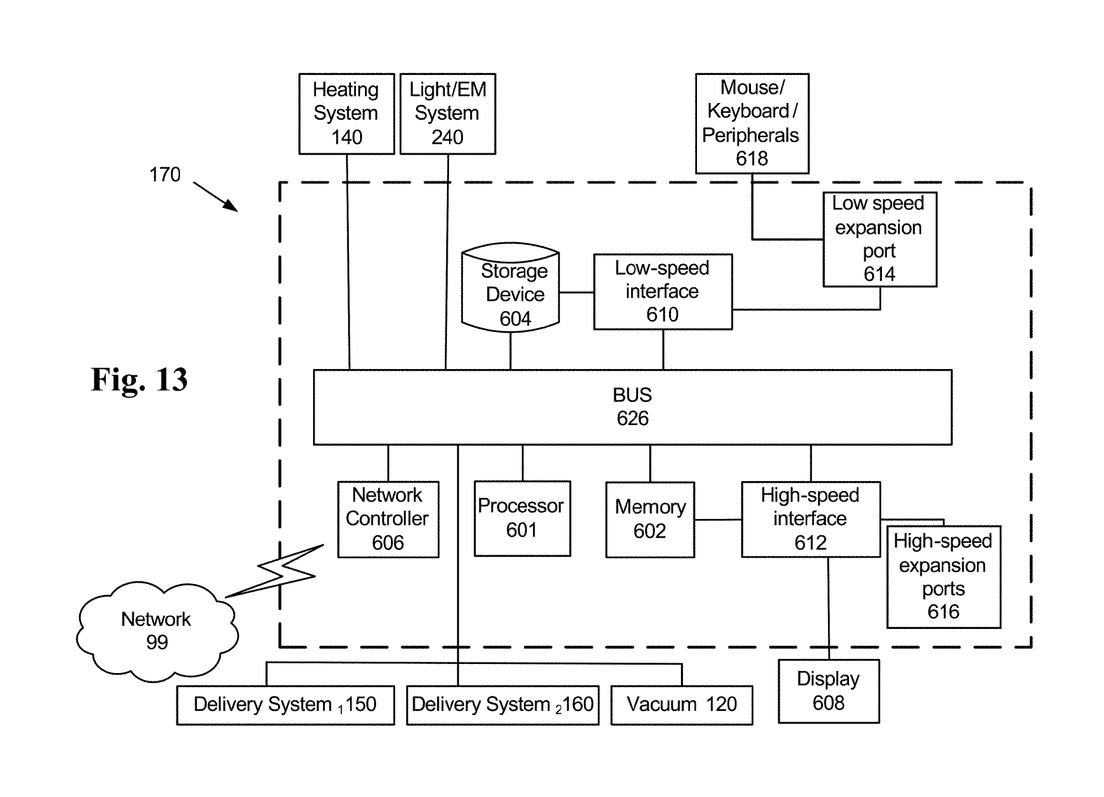

A hardware description of an exemplary computing device 170 used in accordance with embodiments herein is described with reference to FIG. 13. Computing device 170 can be used in conjunction with ALE system 100, 200, 300, or 400. Delivery system₁ 150 is used for delivering a first gas source to the processing chamber 110, 210, 310, or 410. Delivery system₂ 160 is used for delivering a second gas source to the processing chamber 110, 210, 310, or 410. Vacuum system 120 controls the vacuum parameters to the processing chamber 110, 210, 310, or 410.

Embodiments herein describe a first energy activation system of heating system 140 connected to bus 626 in FIG. 13, such as heating system 140 illustrated in FIG. 1. A second energy activation system of light/electromagnetic radiation system 240 is also connected to bus 626 in FIG. 13, such as the light/electromagnetic radiation system 240 illustrated in FIG. 6.

Computing device 600 is intended to represent various forms of digital hardware, such as laptops, desktops, workstations, personal digital assistants, servers, blade servers, mainframes, and other appropriate computers. The components shown here, their connections and relationships, and their functions are meant to be examples only and are not meant to be limiting.

The computing device 600 includes a processor 601, a memory 602, a storage device 604, a high-speed interface 612 connecting to the memory 602 and multiple high-speed expansion ports 616, and a low-speed interface 610 connecting to a low-speed expansion port 614 and the storage device 604. Each of the processor 601, the memory 602, the storage device 604, the high-speed interface 612, the high-speed expansion ports 616, and the low-speed interface 610 are interconnected using various busses, such as communication bus 626, and may be mounted on a common motherboard or in other manners as appropriate.

The processor 601 can process instructions for execution within the computing device 600, including instructions stored in the memory 602 or on the storage device 604 to display graphical information for a GUI on an external input/output device, such as a display 608 coupled to the high-speed interface 612. In other implementations, multiple processors and/or multiple buses may be used, as appropriate, along with multiple memories and types of memory. Also, multiple computing devices may be connected, with each device providing portions of the necessary operations (e.g., as a server bank, a group of blade servers, or a multi-processor system). The memory 602 stores information within the computing device 600. In some implementations, the memory 602 is a volatile memory unit or units. In some implementations, the memory 602 is a non-volatile memory unit or units. The memory 602 can also be another form of computer-readable medium, such as a magnetic or optical disk.

The storage device 604 is capable of providing mass storage for the computing device 600. In some implementations, the storage device 604 can be or contain a computer-readable medium, such as a floppy disk device, a hard disk device, an optical disk device, a tape device, a flash memory or other similar solid state memory device, or an array of devices, including devices in a storage area network or other configurations. Instructions can be stored in an information carrier. The instructions, when executed by one or more processing devices (for example, processor 601), perform one or more methods, such as those described above. The instructions can also be stored by one or more storage devices, such as computer- or machine-readable mediums (for example, the memory 602, the storage device 604, or memory on the processor 601).

The high-speed interface 612 manages bandwidth-intensive operations for the computing device 600, while the low-speed interface 610 manages lower bandwidth-intensive operations. Such allocation of functions is an example only. In some implementations, the high-speed interface 612 is coupled to the memory 602, the display 608 (e.g., through a graphics processor or accelerator), and to the high-speed expansion ports 616, which may accept various expansion cards (not shown). In the implementation, the low-speed interface 610 is coupled to the storage device 604 and the low-speed expansion port 614. The low-speed expansion port 614, which can include various communication ports (e.g., USB, Bluetooth, Ethernet, wireless Ethernet) can be coupled to one or more input/output devices 618, such as a keyboard, a pointing device, a scanner, or a networking device such as a switch or router, e.g., through a network adapter.

The computing device 600 also includes a network controller 606, such as an Intel Ethernet PRO network interface card from Intel Corporation of America, for interfacing with a network 99. As can be appreciated, the network 99 can be a public network, such as the Internet, or a private network such as an LAN or WAN network, or any combination thereof and can also include PSTN or ISDN sub-networks. The network 99 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

Although the computing device 600 of FIG. 13 is described as having a storage medium device 604, the claimed advancements are not limited by the form of the computer-readable media on which the instructions of the described processes are stored. For example, the instructions can be stored on CDs, DVDs, in FLASH memory, RAM, ROM, PROM, EPROM, EEPROM, hard disk, or any other information processing device with which the computing device communicates.

In other alternate embodiments, processing features according to the present disclosure may be implemented and commercialized as hardware, a software solution, or a combination thereof. Moreover, instructions corresponding to processes described herein could be stored in a portable drive, such as a USB Flash drive that hosts a secure process.

Computer programs (also known as programs, software, software applications, or code) associated with the processes described herein include machine instructions for a programmable processor, and can be implemented in a high-level procedural and/or object-oriented programming language, and/or in assembly/machine language. As used herein, the terms machine-readable medium and computer-readable medium refer to any computer program product, apparatus, and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term machine-readable signal refers to any signal used to provide machine instructions and/or data to a programmable processor.

To provide for interaction with a user, the systems and techniques described herein can be implemented on a computer having a display device 608 (e.g., a CRT (cathode ray tube) or LCD (liquid crystal display) monitor) for displaying information to the user and a keyboard and a pointing device 618 (e.g., a mouse or a trackball) by which the user can provide input to the computer. Other kinds of devices can be used to provide for interaction with a user as well. For example, feedback provided to the user can be any form of sensory feedback (e.g., visual feedback, auditory feedback, or tactile feedback), and input from the user can be received in any form, including acoustic, speech, or tactile input.

The systems and techniques described herein can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (LAN), a wide area network (WAN), and the Internet.

The computing system can include clients and servers. A client and server are generally remote from each other and typically interact through a communication network. The relationship of client and server arises by virtue of computer programs running on the respective computers and having a client-server relationship to each other.

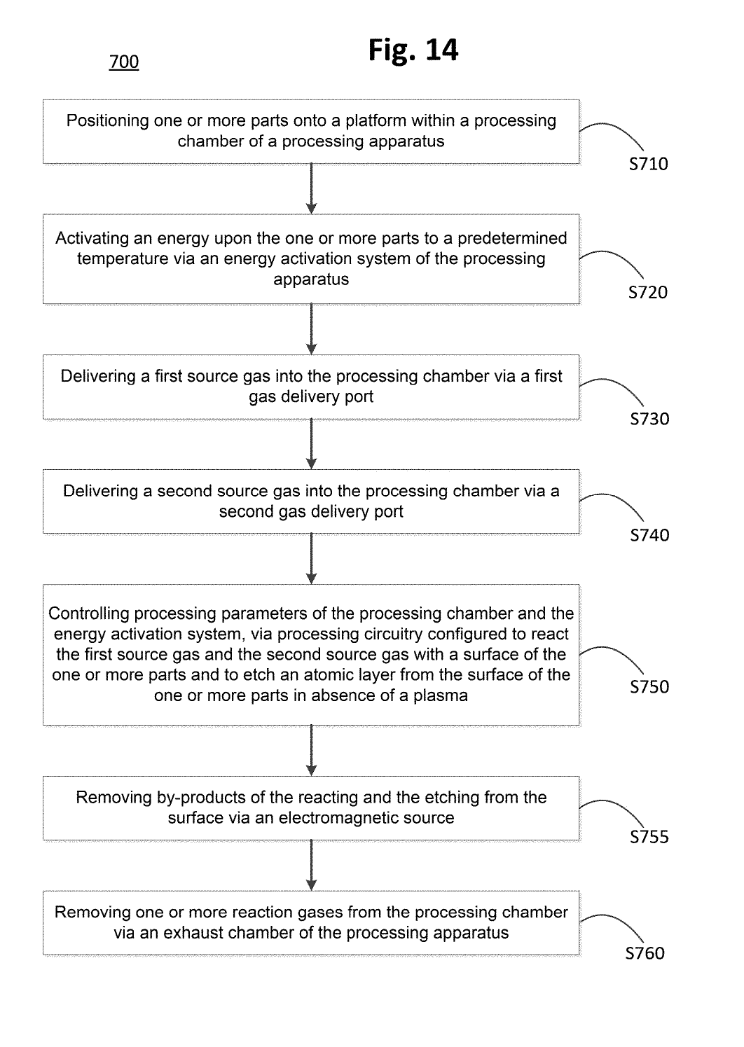

FIG. 14 is a flowchart for an exemplary method 700 of etching a surface of a part, substrate, or wafer. In step S710, one or more parts are positioned onto a platform within a processing chamber of a processing apparatus. In one embodiment, the platform and processing chamber are configured to hold and process a plurality of parts, such as substrates or wafers. In a second embodiment, the processing chamber has a plurality of sub-chambers, and the one or more parts are channeled through the sub-chambers according to processing parameters.

In step S720, an energy is activated upon the one or more parts to a predetermined temperature, via an energy activation system of the processing apparatus. In one embodiment, the energy activation system is a heating system. In a second embodiment, the energy activation system is a radiation system.

In step S730, a first source gas is delivered into the processing chamber via a first gas delivery port. In one embodiment, the first source gas is a fluorine-containing source gas.

In step S740, a second source gas is delivered into the processing chamber via a second gas delivery port. In one embodiment, the second source gas is a metal organic source gas.

In step S750, processing parameters of the processing chamber and the energy activation system are controlled, via processing circuitry. The processing circuitry is configured to react the first source gas and the second source gas with a surface of the one or more parts and to etch an atomic layer from the surface of the one or more parts in absence of a plasma.

In step S755, by-products of the reacting and the etching are removed from the surface, via an electromagnetic source.

In step S760, one or more reaction gases are removed from the processing chamber via an exhaust chamber of the processing apparatus. In one embodiment, the one or more reaction gases are fluoride-containing volatile compounds, which result from reacting a fluorine-containing source gas and a metal organic source gas with the surface of the one or more parts.

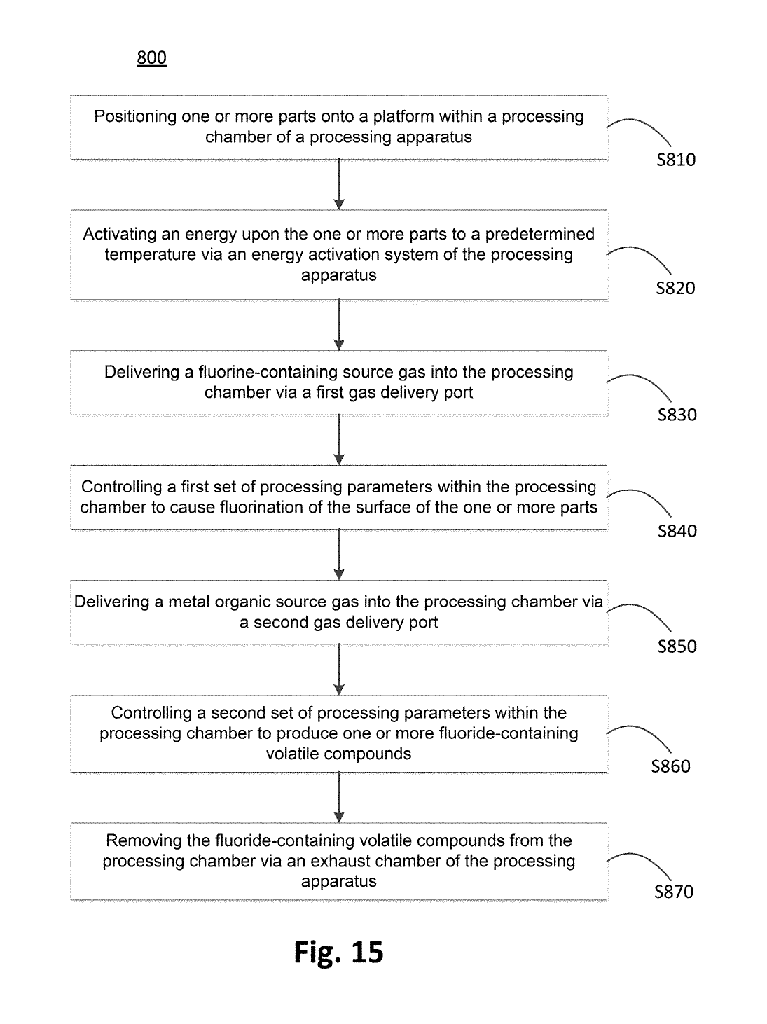

FIG. 15 is a flowchart for an alternative method 800 of etching a surface of a part. In step S810, one or more parts are positioned onto a platform within a processing chamber of a processing apparatus. In one embodiment, the platform and processing chamber are configured to hold and process a plurality of parts, such as substrates or wafers. In a second embodiment, the processing chamber has a plurality of sub-chambers, and the one or more parts are channeled through the sub-chambers according to processing parameters.

In step S820, an energy is activated upon the one or more parts to a predetermined temperature, via an energy activation system of the processing apparatus. In one embodiment, the energy activation system is a heating system. In a second embodiment, the energy activation system is a radiation system.

In step S830, a fluorine-containing source gas is delivered into the processing chamber via a first gas delivery port. In step S840, a first set of processing parameters are controlled within the processing chamber to cause fluorination of the surface of the one or more parts.

In step S850, a metal organic source gas is delivered into the processing chamber via a second gas delivery port. In step S860, a second set of processing parameters are controlled within the processing chamber to produce one or more fluoride-containing volatile compounds.

In step S870, the fluoride-containing volatile compounds are removed from the processing chamber via an exhaust chamber of the processing apparatus. The fluoride-containing volatile compounds result from reacting the fluorine-containing source gas and the metal organic source gas with the surface of the one or more parts.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Embodiments described herein provide advantages over conventional systems and processes, wherein a single atomic or molecular layer can be etched without using a plasma. Therefore, the remaining layers of the part, substrate, or wafer are not damaged by a plasma.

Embodiments described herein include the following aspects.

(1) A processing apparatus includes a processing chamber having a substrate holder; a first gas delivery system configured to deliver a first source gas within the processing chamber; a second gas delivery system configured to deliver a second source gas within the processing chamber; an energy activation system; and processing circuitry. The processing circuitry is configured to control first processing parameters for delivery of the first source gas, control second processing parameters for delivery of the second source gas, control processing chamber parameters and energy activation system parameters to cause a reaction of the first source gas and the second source gas with a surface of one or more parts in the processing chamber to etch an atomic layer from the surface of the one or more parts in absence of a plasma, and control vacuum system parameters for removal of one or more reaction gases from the processing chamber.

(2) The processing apparatus of (1), wherein the processing chamber is configured to treat a plurality of parts simultaneously within the processing chamber.

(3) The processing apparatus of either (1) or (2), wherein the energy activation system comprises a radiation system.

(4) The processing apparatus of any one of (1) through (3), wherein the radiation system comprises an electromagnetic source.

(5) The processing apparatus of any one of (1) through (4), wherein the processing circuitry is further configured to expose radiation having two or more light wavelengths within the processing chamber.

(6) The processing apparatus of any one of (1) through (5), wherein the processing apparatus is configured to atomic layer etch a plurality of parts simultaneously within the processing chamber.

(7) The processing apparatus of any one of (1) through (6), wherein the processing circuitry is further configured to simultaneously deliver the first source gas and the second source gas within the processing chamber.

(8) The processing apparatus of any one of (1) through (7), wherein the processing circuitry is further configured to cycle sequential delivery of the first source gas and the second source gas within the processing chamber.

(9) The processing apparatus of any one of (1) through (8), wherein the processing circuitry is further configured to continuously flow the first source gas and pulse flow the second source gas simultaneously within the processing chamber.

(10) The processing apparatus of any one of (1) through (9), wherein the processing chamber comprises a plurality of sub-chambers, and the processing circuitry is further configured to move the one or more parts sequentially through the plurality of sub-chambers.

(11) The processing apparatus of any one of (1) through (10), wherein the processing circuitry is further configured to sequentially etch a plurality of atomic monolayers from the surface of the part.

(12) A method of etching a surface of a part includes positioning one or more parts onto a substrate holder within a processing chamber of a processing apparatus; activating an energy upon the one or more parts to a predetermined temperature via an energy activation system of the processing apparatus; delivering a first source gas into the processing chamber via a first gas delivery system; delivering a second source gas into the processing chamber via a second gas delivery system; controlling processing parameters of the processing chamber and the energy activation system, via processing circuitry configured to react the first source gas and the second source gas with a surface of the one or more parts and to etch an atomic layer from the surface of the one or more parts in absence of a plasma; removing, via an electromagnetic source, by-products of the reacting and the etching from the surface; and removing one or more reaction gases from the processing chamber via an exhaust chamber of the processing apparatus.

(13) The method of etching a surface of a part of (12), further includes delivering a fluorine-containing source gas into the processing chamber via the first gas delivery system; controlling a first set of processing parameters within the processing chamber to cause fluorination of the surface of the one or more parts; delivering a metal organic source gas into the processing chamber via the second gas delivery system; and controlling a second set of processing parameters within the processing chamber to produce one or more fluoride-containing volatile compounds.

(14) The method of etching a surface of a part of either (12) or (13), wherein the first source gas and the second source gas are delivered into the processing chamber simultaneously.

(15) The method of etching a surface of a part of any one of (12) through (14), wherein the first source gas and the second source gas are alternately delivered into the processing chamber.

(16) The method of etching a surface of a part of any one of (12) through (15), wherein the first source gas is flowed continuously into the processing chamber while the second source gas is simultaneously pulse flowed into the processing chamber.

(17) The method of etching a surface of a part of any one of (12) through (16), wherein parameters of the energy activation system are determined in part by a material of the part being treated and by a material of the first source gas and the second source gas.

(18) A processing apparatus, including a processing chamber having a substrate holder, a first gas delivery system configured to deliver a first source gas within the processing chamber, a second gas delivery system configured to deliver a second source gas within the processing chamber, an energy activation system, an exhaust chamber, and a means for controlling parameters of the processing chamber and the energy activation system to etch an atomic layer from a surface of one or more parts within the processing chamber in absence of a plasma.

(19) The processing apparatus of (18), wherein the means further includes continuously flowing the first source gas and pulse flowing the second source gas simultaneously within the processing chamber.

(20) The processing apparatus of either (18) or (19), wherein the energy activation system comprises one of a heating system and a radiation system.

While certain embodiments have been described herein, these embodiments are presented by way of example only, and are not intended to limit the scope of the disclosure. Using the teachings in this disclosure, a person having ordinary skill in the art can modify and adapt the disclosure in various ways, making omissions, substitutions, and/or changes in the form of the embodiments described herein, without departing from the spirit of the disclosure. Moreover, in interpreting the disclosure, all terms should be interpreted in the broadest possible manner consistent with the context. The accompanying claims and their equivalents are intended to cover such forms or modifications, as would fall within the scope and spirit of the disclosure.

1. A processing apparatus, comprising:
a processing chamber including a substrate holder;
a first gas delivery system configured to deliver a first source gas within the processing chamber;
a second gas delivery system configured to deliver a second source gas within the processing chamber;
an energy activation system; and
processing circuitry, configured to
control first processing parameters for delivery of the first source gas,
control second processing parameters for delivery of the second source gas,
control processing chamber parameters and energy activation system parameters to cause a reaction of the first source gas and the second source gas with a surface of one or more parts in the processing chamber to etch an atomic layer from the surface of the one or more parts in absence of a plasma, and
control vacuum system parameters for removal of one or more reaction gases from the processing chamber.

2. The processing apparatus of claim 1, wherein the processing chamber is configured to treat a plurality of parts simultaneously within the processing chamber.

3. The processing apparatus of claim 1, wherein the energy activation system comprises a radiation system.

4. The processing apparatus of claim 3, wherein the radiation system comprises an electromagnetic source.

5. The processing apparatus of claim 3, wherein the processing circuitry is further configured to expose radiation having two or more light wavelengths within the processing chamber.

6. The processing apparatus of claim 1, wherein the processing apparatus is configured to atomic layer etch a plurality of parts simultaneously within the processing chamber.

7. The processing apparatus of claim 1, wherein the processing circuitry is further configured to simultaneously deliver the first source gas and the second source gas within the processing chamber.

8. The processing apparatus of claim 1, wherein the processing circuitry is further configured to cycle sequential delivery of the first source gas and the second source gas within the processing chamber.

9. The processing apparatus of claim 1, wherein the processing circuitry is further configured to continuously flow the first source gas and pulse flow the second source gas simultaneously within the processing chamber.

10. The processing apparatus of claim 1, wherein the processing chamber comprises a plurality of sub-chambers, and the processing circuitry is further configured to move the one or more parts sequentially through the plurality of sub-chambers.

11. The processing apparatus of claim 1, wherein the processing circuitry is further configured to sequentially etch a plurality of atomic monolayers from the surface of the part.

12. A method of etching a surface of a part, the method comprising:
positioning one or more parts onto a substrate holder within a processing chamber of a processing apparatus;
activating an energy upon the one or more parts to a predetermined temperature via an energy activation system of the processing apparatus;
delivering a first source gas into the processing chamber via a first gas delivery system;
delivering a second source gas into the processing chamber via a second gas delivery system;
controlling processing parameters of the processing chamber and the energy activation system, via processing circuitry configured to react the first source gas and the second source gas with a surface of the one or more parts and to etch an atomic layer from the surface of the one or more parts in absence of a plasma;
removing, via an electromagnetic source, by-products of the reacting and the etching from the surface; and
removing one or more reaction gases from the processing chamber via an exhaust chamber of the processing apparatus.

13. The method of claim 12, further comprising:
delivering a fluorine-containing source gas into the processing chamber via the first gas delivery system;
controlling a first set of processing parameters within the processing chamber to cause fluorination of the surface of the one or more parts;
delivering a metal organic source gas into the processing chamber via the second gas delivery system; and
controlling a second set of processing parameters within the processing chamber to produce one or more fluoride-containing volatile compounds.

14. The method of claim 12, wherein the first source gas and the second source gas are delivered into the processing chamber simultaneously.

15. The method of claim 12, wherein the first source gas and the second source gas are alternately delivered into the processing chamber.

16. The method of claim 12, wherein the first source gas is flowed continuously into the processing chamber while the second source gas is simultaneously pulse flowed into the processing chamber.

17. The method of claim 12, wherein parameters of the energy activation system are determined in part by a material of the part being treated and by a material of the first source gas and the second source gas.

18. A processing apparatus, comprising:
a processing chamber including a substrate holder;
a first gas delivery system configured to deliver a first source gas within the processing chamber;
a second gas delivery system configured to deliver a second source gas within the processing chamber;
an energy activation system;
an exhaust chamber; and
a means for controlling parameters of the processing chamber and the energy activation system to etch an atomic layer from a surface of one or more parts within the processing chamber in absence of a plasma.

19. The vacuum processing apparatus of claim 18, wherein the means further includes continuously flowing the first source gas and pulse flowing the second source gas simultaneously within the processing chamber.

20. The vacuum processing apparatus of claim 18, wherein the energy activation system comprises one of a heating system and a radiation system.
